(19) United States
(12) Patent Application Publication
(10) Pub. No.: US 2022/0393075 A1
(43) Pub. Date: Dec. 8, 2022

(54) DISPLAY PANELS, DISPLAY APPARATUSES AND METHODS OF MANUFACTURING DISPLAY PANELS

(71) Applicant: BOE Technology Group Co., Ltd., Beijing (CN)

(72) Inventors: Haixu LI, Beijing (CN); Guangcai YUAN, Beijing (CN)

(21) Appl. No.: 17/762,939

(22) PCT Filed: Mar. 1, 2021
(86) PCT No.: PCT/CN2021/078417

§ 371 Date: Mar. 23, 2022

(30) Foreign Application Priority Data
Apr. 22, 2020 (CN) 202010320861.3

(51) Int. Cl. H01L 33/46; H01L 25/16

(52) U.S. Cl. CPC H01L 33/46; H01L 25/167; H01L 2933/0025; H01L 24/05

(57) ABSTRACT

Provided is a display panel, including a drive backplate, light emitting elements and a light reflecting layer located on the drive backplate, where the light reflecting layer includes a first light reflecting layer made of a metal and wrapping sidewalls of the light emitting elements, and the first light reflecting layer is configured to enable light emitted by each of the light emitting elements to be guided out from a top portion of the light emitting element. Further provided are a display apparatus and a method of manufacturing a display panel.

### TECHNICAL FIELD

One or more embodiments of the present disclosure relate to display panels, display apparatuses, and methods of manufacturing display panels.

### BACKGROUND

Micro-LED or mini-LED achieves smart phone or virtual reality screens with high resolution, for example, 4K or even 8K resolution and the like. But, Micro-LED and mini-LED are both point light sources and thus have the characteristics of point light sources. In use, most of the light they emit cannot be utilized during operation.

### SUMMARY

At least one embodiment of the present disclosure provides a display panel, including a drive backplate, light emitting elements and a light reflecting layer located on the drive backplate, where the light reflecting layer includes a first light reflecting layer wrapping sidewalls of the light emitting elements, and the first light reflecting layer is configured to enable light emitted by each of the light emitting elements to be guided out from a top portion of the light emitting element.

In an embodiment of the present disclosure, a difference between a height of a top end of the first light reflecting layer relative to the drive backplate and a height of the top portion of the light emitting element relative to the drive backplate is smaller than 1 micron.

In an embodiment of the present disclosure, the display panel further includes an insulation component, where the insulation component is at least disposed between a bottom surface of the light emitting element and the drive backplate and configured to electrically isolate the light reflecting layer from a bottom portion of the light emitting element.

In an embodiment of the present disclosure, the light reflecting layer further includes a second light reflecting layer located between adjacent light emitting elements, and the second light reflecting layer is disposed on the drive backplate and formed with the first light reflecting layer into one-piece structure.

In an embodiment of the present disclosure, the display panel further includes an insulation component, where the insulation component covers the drive backplate, and is configured to electrically isolate the light reflecting layer from a bottom portion of the light emitting element.

In an embodiment of the present disclosure, the light reflecting layer further includes a second light reflecting layer located between adjacent light emitting elements, and the second light reflecting layer is disposed on the insulation component and formed with the first light reflecting layer into one-piece structure.

In an embodiment of the present disclosure, the light reflecting layer further includes a second light reflecting layer located between adjacent light emitting elements, and the second light reflecting layer is parallel to the drive backplate and formed with the first light reflecting layer into one-piece structure.

In an embodiment of the present disclosure, the drive backplate includes an insulation layer, and the second light reflecting layer is located on the insulation layer.

In an embodiment of the present disclosure, the display panel further includes an insulation component, where the insulation component is configured to electrically isolate the light reflecting layer from the bottom portion of the light emitting element.

In an embodiment of the present disclosure, the insulation component is a planarization layer formed on the insulation layer, and the second light reflecting layer is located on the planarization layer.

In an embodiment of the present disclosure, the light reflecting layer is made of a metal, and the metal includes at least one of aluminum or silver.

In an embodiment of the present disclosure, the display panel further includes a light blocking layer, and the light blocking layer is located at a side of the second light reflecting layer away from the drive backplate.

At least one embodiment of the present disclosure provides a display apparatus, including any one of the above display panels.

At least one embodiment of the present disclosure provides a method of manufacturing a display panel, including:

placing a plurality of light emitting elements on a drive backplate;

forming a light reflecting film layer, where the light reflecting film layer at least covers sidewalls and a top surface of each of the plurality of light emitting elements;

coating a photoresist, wherein the photoresist exposes parts of the light reflecting film layer on the top surfaces of the plurality of light emitting elements; and,

etching the parts of the light reflecting film layer on the top surfaces of the plurality of light emitting elements to form a first light reflecting layer wrapping the sidewalls of the light emitting elements.

In an embodiment of the present disclosure, the light reflecting film layer is made of a metal, and the metal includes at least one of aluminum or silver.

In an embodiment of the present disclosure, the method includes forming the light reflecting film layer by sputtering.

In an embodiment of the present disclosure, the method further includes forming an insulation component at least between a bottom surface of the light emitting element and the drive backplate before forming the light reflecting film layer, where the insulation component isolates the light reflecting film layer and a bottom portion of the light emitting element in an insulating manner.

In an embodiment of the present disclosure, the light reflecting film layer further covers the drive backplate, and integrally forming a second light reflecting layer covering the drive backplate while forming the first light reflecting layer.

In an embodiment of the present disclosure, the method further includes forming an insulation component covering the drive backplate before forming the light reflecting film layer, where the insulation component isolates the light reflecting film layer from a bottom portion of the light emitting element in an insulating manner.

In an embodiment of the present disclosure, the light reflecting film layer further covers the insulation component, and integrally forming a second light reflecting layer covering the insulation component while forming the first light reflecting layer.

In an embodiment of the present disclosure, the method further includes removing the photoresist filled between any two adjacent light emitting elements and forming a light blocking layer between the any two adjacent light emitting elements.

In an embodiment of the present disclosure, the light blocking layer is made of a black organic material.

The technical solution provided by the embodiments of the present disclosure at least has the following beneficial effects.

Since the light reflecting layer at least wraps the sidewalls of the light emitting elements and light emitted by the light emitting elements is reflected on the light reflecting layer, the light emitted by the light emitting elements can be emitted out from the top portions of the light emitting elements as possible, thereby improving the light emission efficiency and enhancing the display effect. Particularly, the light reflecting layer cooperates with a light emitting surface of the light emitting elements, such that all light emitted by the light emitting elements can be emitted out from the top portions of the light emitting elements, further improving the light emission efficiency and enhancing the display effect. Furthermore, the light reflecting layer can be prepared using a device for preparing the backplate. During a preparation process, resin exposure depth and coating uniformity can be easily controlled. Therefore, the manufacture difficulty of such light reflecting layers is low.

It should be understood that the above general descriptions and subsequent detailed descriptions are merely illustrative and explanatory rather than limiting of the present disclosure.

### BRIEF DESCRIPTION OF THE DRAWINGS

The accompanying drawings, which are incorporated in and constitute a part of the present description, illustrate examples consistent with the present disclosure and serve to explain the principles of the present disclosure together with the description.

FIG. 1 is a diagram illustrating a structure of a display panel according to an embodiment of the present disclosure.

FIG. 2 is a flowchart illustrating a method of manufacturing a display panel according to an embodiment of the present disclosure.

FIGS. 3-8 are diagrams illustrating structures formed by performing various process steps for manufacturing a display panel according to an embodiment of the present disclosure.

FIG. 9 illustrates path of light emitted by a light emitting element and reflected by a light reflecting layer.

### DETAILED DESCRIPTION OF THE EMBODIMENTS

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

The terms used in the present disclosure are for the purpose of describing particular examples only, and are not intended to limit the present disclosure. Terms determined by “a”, “the” and “said” in their singular forms in the present disclosure and the appended claims are also intended to include plurality, unless clearly indicated otherwise in the context.

The terms “first” “second” and the like used in the specification and claims do not represent any sequence, quantity or importance, but distinguish different components. Similarly, “one” or “a” and the like do not represent quantity limitation but represent at least one. “Multiple” or “a plurality” represents two or more. Unless otherwise stated, the words such as “front”, “rear”, “lower” and/or “upper” are used only for ease of descriptions rather than limited to one position or a spatial orientation. Unless otherwise stated, “include” or “contain” or the like is intended to refer to that an element or object appearing before “include” or “contain” covers an element or object or its equivalents listed after “include” or “contain” and does not preclude other elements or objects.

In combination with accompanying drawings, the embodiments of the present disclosure will be detailed below. In case of no conflicts, the embodiments and the features of the embodiments described below may be supplemented or combined with each other.

To guide out light emitted by a light emitting element as possible and use most of the light, one technology known to the inventor is to prepare a white resin of 70 um-100 um around the light emitting element as a light reflecting layer. But, it is difficult to control the resin exposure depth and coating uniformity. Such a light reflecting layer is relatively difficult to manufacture and achieve.

In the present disclosure, a thin film (light reflecting white material such as Al and Ag) for guiding light is prepared around light emitting elements, and the thin film is used as a light reflecting layer. The technical solution will be described in detail below.

At least one embodiment of the present disclosure provides a display panel. As shown in FIG. 1, the display panel includes a drive backplate 1, a plurality of light emitting elements 2 and a light reflecting layer 3 located on the drive backplate 1. The light reflecting layer 3 at least includes a first light reflecting layer 31 wrapping sidewalls of the light emitting elements 2. In an embodiment of the present disclosure, the drive backplate may be a TFT (Thin Film Transistor) substrate. In an embodiment of the present disclosure, the light emitting element may be a Micro-LED or mini-LED. In an embodiment of the present disclosure, the drive backplate 1 includes a substrate 11, a blocking layer 12 for blocking water vapor and impurity, a first gate insulation layer 13, a second gate insulation layer 14, a dielectric layer 15 for insulation, a first planarization layer 16, an insulation layer 17, and a second planarization layer 18 from bottom to top. Further, in addition to the first light reflecting layer 31 wrapping the sidewalls of the light emitting elements 2, the light reflecting layer 3 further includes a second light reflecting layer 32 disposed between adjacent light emitting elements 2 and parallel to the substrate 11. In a case that the light reflecting layer 3 includes the second light reflecting layer 32, the first light reflecting layer 31 and the second light reflecting layer 32 may be formed by metal sputtering process, and the first light reflecting layer 31 and the second light reflecting layer 32 are formed into one-piece structure. In this way, the process is simple. In the present disclosure, the light reflecting layer is configured to include the first light reflecting layer 31 wrapping the sidewalls of the light emitting elements 2 and/or the second light reflecting layer 32 disposed between adjacent light emitting elements 2 and paralleled to the substrate 11, and the light emitting elements 2 are powered by a cathode and an anode below to emit light, and thus, there is no electrical contact between the light reflecting layer 3 and the light emitting elements 2. Furthermore, the light emitting element 2 itself has one layer of inorganic protective layer (except for surfaces of pins of the cathode and the anode, the remaining surfaces of the light emitting element 2 are covered by the inorganic layer), and thus no mutual influence may be caused between the light emitting element 2 and the light reflecting layer 3. In addition, an insulation component may be disposed. The insulation component is configured to isolate bottom portion of the light emitting element 2 from the light reflecting layer in an electrical insulation manner. In an embodiment of the present disclosure, the light reflecting layer 3 is configured to enable light emitted by each of the light emitting elements 2 to be guided out from a top portion of the light emitting element 2. The following descriptions will be made to how the light reflecting layer 3 guides out the light of the light emitting element 2.

As shown in FIG. 9, since the light emitting element 2 is a point light source, it emits light radially and some of the light may not be emitted along a vertical direction indicated by the arrow in the FIG. 9 but reach the sidewalls of the light emitting element 2, for example, the light that reaches a left sidewall and is then reflected from the left sidewall shown in the FIG. 9. When the sidewalls of the light emitting element 2 are wrapped by the first light reflecting layer 31, the light emitted by the light emitting element 2 is reflected upward on the first light reflecting layer 31 as shown in FIG. 8. As a result, the light emitted by the light emitting element 2 can all be emitted from the top portion of the light emitting element 2, improving the light emission effect and enhancing the display effect. In an embodiment of the present disclosure, the light reflecting layer 3 cooperates with a light emitting surface 21 of the light emitting element 2 parallel to the substrate, such that all light emitted by the light emitting element 2 can be emitted out from the top portion of the light emitting element 2, further improving the light emission efficiency and enhancing the display effect. Furthermore, the light reflecting layer 3 may be prepared using a device for preparing the backplate. During a preparation process, the resin exposure depth and coating uniformity are easily controlled, and therefore, such light reflecting layer 3 is easy to prepare.

In an embodiment of the present disclosure, to guarantee the light emission efficiency, a difference between a height of a top end of the light reflecting layer 3 relative to the drive backplate 1 and a height of the light emitting element 2 relative to the drive backplate 1 is smaller than 1 micron. That is, if the height of the top surface of the light reflecting layer 3 relative to the drive backplate 1 is H1 and the height of the top surface of the light emitting element 2 relative to the drive backplate 1 is H2, H2−H1<1 μm (unit: micron). In the FIGS. 1 and 7-9, the top surface of the light reflecting layer 3 is flush with the top surface of the light emitting element 2.

In the present disclosure, no matter whether the light reflecting layer 3 includes the second light reflecting layer 32, to prevent short circuiting resulting from electrical connection of the light reflecting layer 3 and a welding pad (for example, metal wire, metal block and the like) at the bottom portion of the light emitting element 2, the display panel further includes an insulation component. The insulation component is located on the insulation layer 17 and electrically insulates the light reflecting layer 3 from the bottom portion of the light emitting element 2. To enable the insulation component to electrically insulate the light reflecting layer 3 from the bottom portion of the light emitting element 2, the insulation component is configured to surround the welding pad at the bottom portion of the light emitting element. For example, the insulation component is disposed along a lower edge 22 of the sidewalls of the light emitting element 2 to electrically isolate the light reflecting layer from the welding pad at the bottom portion of the light emitting element. In some examples, the insulation component is located between a bottom surface of the light emitting element 2 and the insulation layer 17 of the drive backplate 1. In this case, the insulation component and the insulation layer 17 sealingly wrap the welding pad at the bottom surface of the light emitting element 2, such that the light reflecting layer 3 is insulated electrically from the bottom portion of the light emitting element. In some examples, before the light reflecting layer is formed, a planarization layer is disposed on the insulation layer 17 and then the light reflecting layer is formed on the planarization layer and the sidewalls of the light emitting element 2. In this way, the planarization layer can electrically insulate the light reflecting layer 3 from the bottom portion of the light emitting element. No matter how the insulation component is disposed, it cooperates with the insulation layer 17 to wrap the welding pad at the bottom portion of the light emitting element 2, so as to isolate the light reflecting layer 3 from the welding pad. For the above cases, when the light reflecting layer 3 includes the first light reflecting layer 31 and the second light reflecting layer 32, the second light reflecting layer 32 can be disposed in the following manner.

1) For the case that the insulation component is not located between adjacent light emitting elements 2, the second light reflecting layer 32 is located on the insulation layer 17 and the insulation component is located under the second light reflecting layer 32.

2) For the case that the insulation component is located between adjacent light emitting elements 2, the insulation component is a planarization layer formed on the insulation layer 17 (a second planarization layer 18 as shown in FIGS. 1, and 4-9), and the second light reflecting layer 32 is located on the planarization layer (the second planarization layer 18). In this configuration, by forming the planarization layer (the second planarization layer 18) using the device for preparing the backplate, a coating amount can be easily controlled, and manufacture difficulty is reduced.

In other words, when the insulation component is disposed between the bottom surface of the light emitting element and the drive backplate, the second light reflecting layer is directly disposed on the drive backplate; and when the insulation component (i.e. the second planarization layer 18) covers the drive backplate, the second light reflecting layer is disposed on the insulation component.

In an embodiment of the present disclosure, the display panel includes a light blocking layer 4 on the second light reflecting layer 32 located between adjacent light emitting elements 2. With disposal of the light blocking layer 4, reflection of ambient light by a part other than the light emitting element may be reduced, thereby enhancing the display effect. The light blocking layer 4 may be made of a black organic material.

At least one embodiment of the present disclosure further provides a display apparatus, including the above display panel. The display apparatus may be, for example, smart phone, virtual reality screen, television and the like.

In the display panels and the display apparatuses provided by the present disclosure, because the light reflecting layer at least wraps the sidewalls of the light emitting elements and light emitted by the light emitting elements is reflected on the light reflecting layer, the light emitted by the light emitting elements can be emitted out from the top portions of the light emitting elements as possible, thereby improving the light emission efficiency and enhancing the display effect. Particularly, the light reflecting layer cooperates with the light emitting surface of the light emitting elements, such that all light emitted by the light emitting elements can be emitted out from the top portions of the light emitting elements, further improving the light emission efficiency and enhancing the display effect. Furthermore, the light reflecting layer can be prepared using a device for preparing the backplate. During a preparation process, the resin exposure depth and coating uniformity can be easily controlled. Therefore, the manufacture difficulty of such light reflecting layers is low.

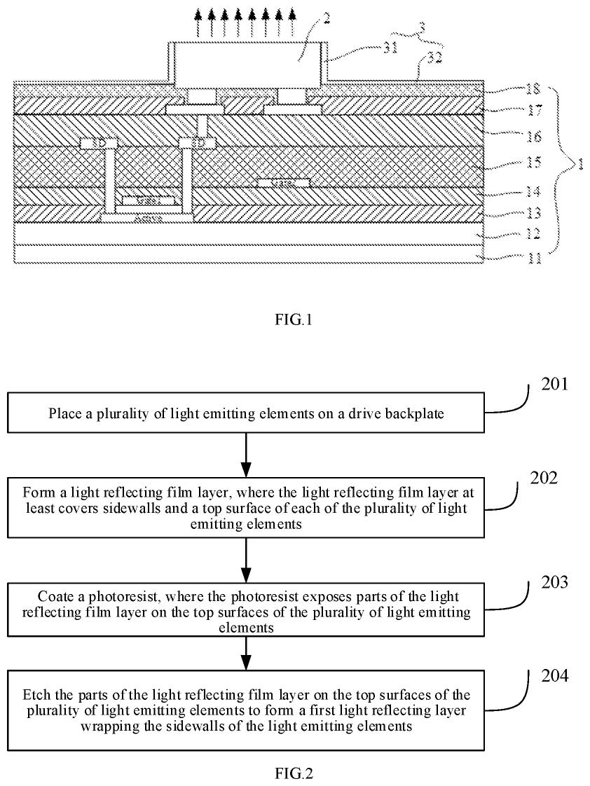

At least one embodiment of the present disclosure provides a method of manufacturing a display panel. As shown in FIG. 2, the method includes the following steps.

201, a plurality of light emitting elements are placed on a first planarization layer of a drive backplate.

202, a light reflecting film layer made of a metal is formed, where the light reflecting film layer at least covers sidewalls and a top surface of each of the plurality of light emitting elements.

203, a photoresist is coated, where the photoresist exposes parts of the light reflecting film layer on the top surfaces of the plurality of light emitting elements.

204, the parts of the light reflecting film layer on the top surfaces of the plurality of light emitting elements are etched to form a first light reflecting layer wrapping the sidewalls of the light emitting elements.

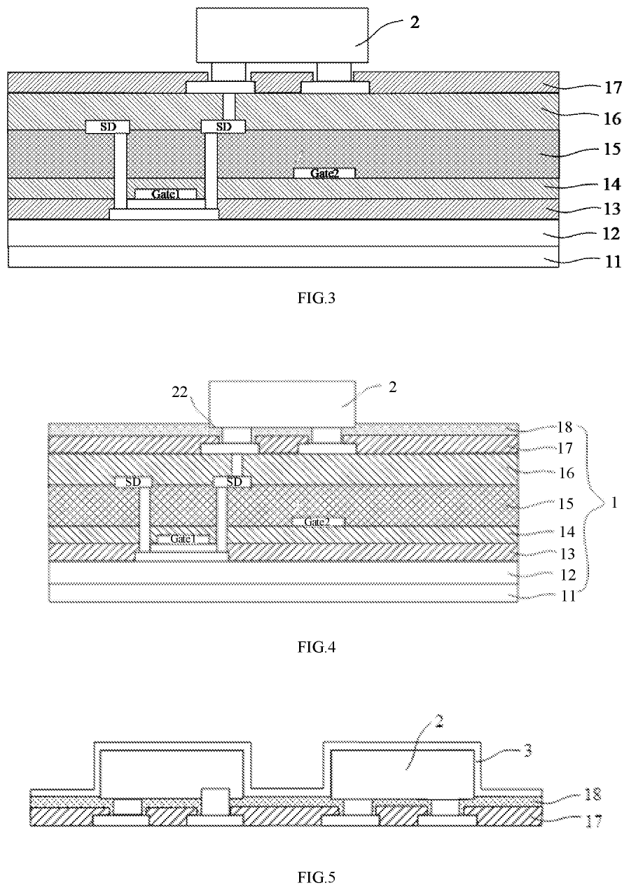

With reference to FIGS. 3-7, a method of manufacturing a display panel according to an embodiment of the present disclosure will be elaborated below.

As shown in FIG. 3, light emitting elements are placed on the drive backplate 1. The drive backplate may be, for example, a TFT substrate. Afterwards, as shown in FIG. 4, an insulation component is formed between the light emitting elements and the drive backplate, and configured to isolate a light reflecting layer formed subsequently from bottom portions of the light emitting elements in an insulating manner. In the structure shown in FIG. 4, the insulation component is formed into a second planarization layer 18 covering an insulation layer 17. In an embodiment of the present disclosure, the insulation component is disposed to surround a lower edge 22 of the sidewalls of the light emitting elements 2. In another embodiment of the present disclosure, an annular insulation component is formed between the bottom surface of the light emitting element 2 and the insulation layer 17 of the drive backplate 1. Regardless of the position and the shape of the insulation component, it is to be guaranteed that the insulation component can electrically isolate a welding pad at the bottom surface of the light emitting element 2 from the light reflecting layer formed subsequently.

In the structure shown in FIG. 4, a material of the second planarization layer 18 may be a common planarization material, such as JEM-608 of acrylic system, or DL-1000 series of polyimide system; or may be a thermally conductive silica gel without electrical conductivity. One or more thin film transistors and their connection lines are formed inside the above layers. For example, an active layer of the thin film transistor may be formed above a blocking layer 12; a gate electrode of the thin film transistor may be formed above a first gate insulation layer 13, and covered by a second gate insulation layer 14; a source/drain region of the thin film transistor may be connected to outside (for example, a cathode and an anode of the light emitting element 2) through a metal connection hole disposed inside the first gate insulation layer 13, the second gate insulation layer 14, a dielectric layer 15 and a first planarization layer 16.

Afterwards, a light reflecting film layer made of a metal is formed. In an embodiment of the present disclosure, the light reflecting film layer may only cover the light emitting elements, namely, cover the top surfaces of the light emitting elements and wrap the sidewalls of the light emitting elements. In another embodiment of the present disclosure, the light reflecting film layer is formed on the entire drive backplate, with a formed structure shown in FIG. 5.

When the light reflecting film layer only covers the top surfaces of the light emitting elements and wraps the sidewalls of the light emitting elements, a person skilled in the art may obtain a first light reflecting layer 31 based on the photo-etching and etching. In the present disclosure, descriptions are made with the light reflecting film layer covering the entire drive backplate as an example.

As shown in FIG. 5, the light reflecting film layer is formed on the entire substrate. For example, the light reflecting film layer may be formed on the planarization layer 18 and the light emitting elements (including the top surface and the sidewalls) by sputtering. The light reflecting film layer may be a single-layer structure made of Al or Ag, or a laminated structure, for example, a laminated structure of Al/ITO or Ag/ITO or the like. In an embodiment of the present disclosure, to reduce the manufacturing costs while guaranteeing the light emission efficiency of the light emitting elements 2, a thickness of the light reflecting film layer is in a range of 500 Å-2000 Å, for example, 500 Å, 600 Å, 700 Å, 800 Å, 900 Å, 1000 Å, 1100 Å, 1200 Å, 1300 Å, 1400 Å, 1500 Å, 1600 Å, 1700 Å, 1800 Å, 1900 Å or 2000 Å.

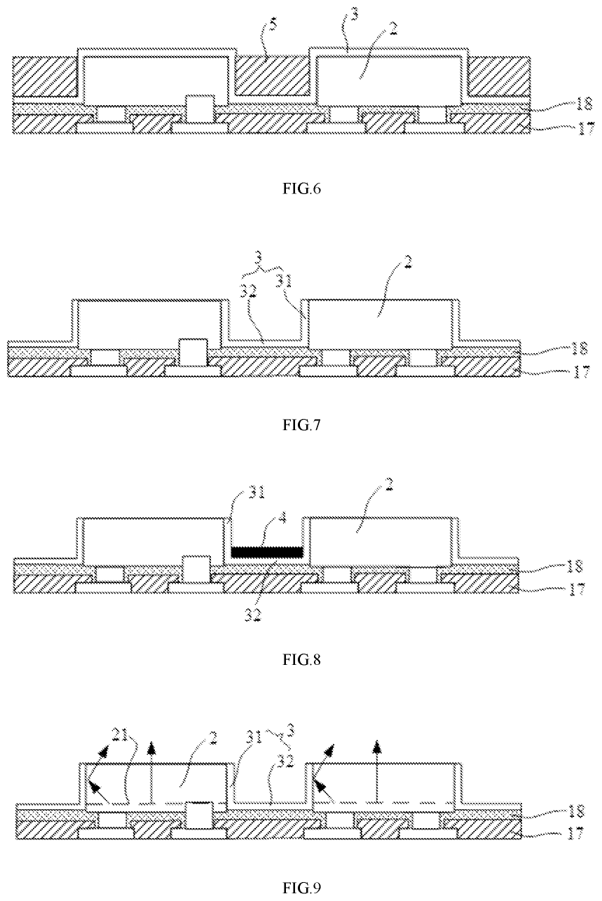

By referring to FIG. 6 and FIG. 5 combined, a photoresist 5 is coated in such a way that the photoresist 5 is filled in a space between adjacent light emitting elements 2 and a part of the light reflecting film layer on the top portions of the light emitting elements 2 is exposed.

By referring to FIG. 7 and FIG. 6 combined, the part of the light reflecting film layer on the top portions of the light emitting elements 2 is etched to remove the light reflecting film layer on the top portions of the light emitting elements 2, and then the photoresist 5 between adjacent light emitting elements 2 is removed. Thus, the light reflecting layer 3 including the first light reflecting layer 31 and the second light reflecting layer 32 is formed.

Those skilled in the art may understand that, when the insulation component is formed only between the bottom portion of the light emitting element and the drive backplate, the light reflecting film layer may directly cover the drive backplate while wrapping the top portion and sidewalls of the light emitting element. In this way, when the first light reflecting layer is formed by etching, the second light reflecting layer disposed on the drive backplate may also be formed at the same time. When the insulation component covers the drive backplate, the light reflecting film layer may directly cover the insulation component while wrapping the top portion and the sidewalls of the light emitting element. In this way, when the first light reflecting layer is formed by etching, the second light reflecting layer disposed on the insulation component may also be formed at the same time.

With reference to FIG. 8, further, in an embodiment of the present disclosure, after the photoresist 5 between adjacent light emitting elements 2 is removed, a black organic material may be prepared between adjacent light emitting elements 2 to form a light blocking layer 4 on the second light reflecting layer between adjacent light emitting elements 2. The light blocking layer 4 may reduce reflection of ambient light by the second light reflecting layer and enhance the display effect.

In the method of manufacturing a display panel according to embodiments of the present disclosure, since the light reflecting layer at least wraps the sidewalls of the light emitting elements and light emitted by the light emitting elements is reflected at the light reflecting layer, the light emitted by the light emitting elements can be emitted out from the top portions of the light emitting elements as possible, thereby improving the light emission efficiency and enhancing the display effect. Particularly, the light reflecting layer cooperates with the light emitting surfaces of the light emitting elements, such that all light emitted by the light emitting elements can be emitted out from the top portions of the light emitting elements, further improving the light emission efficiency and enhancing the display effect. Furthermore, the light reflecting layer can be prepared using a device for preparing the backplate. During a preparation process, resin exposure depth and coating uniformity can be easily controlled. Therefore, the manufacture difficulty of such light reflecting layer is low.

The above descriptions are merely preferred embodiments of the present disclosure rather than intended to limit the present disclosure in any manner. Although the present disclosure is made with preferred embodiments as above, these preferred embodiments are not used to limit the present disclosure. Those skilled in the art may make some changes or modifications to the technical contents of the present disclosure as equivalent embodiments without departing from the scope of the technical solution of the present disclosure. Any simple changes, equivalent changes or modifications made to the above embodiments based on the technical essence of the present disclosure without departing from the contents of the technical solution of the present disclosure shall all fall within the scope of protection of the present disclosure.

1. A display panel, comprising:
a drive backplate,
light emitting elements and a light reflecting layer, located on the drive backplate, wherein
the light reflecting layer comprises a first light reflecting layer wrapping sidewalls of the light emitting elements, and
the first light reflecting layer is configured to enable light emitted by each of the light emitting elements to be guided out from a top portion of the light emitting element.

2. The display panel of claim 1, wherein a difference between a height of a top end of the first light reflecting layer relative to the drive backplate and a height of the top portion of the light emitting element relative to the drive backplate is smaller than 1 micron.

3. The display panel of claim 1, further comprising an insulation component, wherein the insulation component is at least disposed between a bottom surface of the light emitting element and the drive backplate and configured to electrically isolate the light reflecting layer from a bottom portion of the light emitting element.

4. The display panel of claim 1, wherein the light reflecting layer further comprises a second light reflecting layer located between adjacent light emitting elements, and the second light reflecting layer is disposed on the drive backplate and formed with the first light reflecting layer into one-piece structure.

5. The display panel of claim 1, further comprising an insulation component, wherein the insulation component covers the drive backplate, and is configured to electrically isolate the light reflecting layer from a bottom portion of the light emitting element.

6. The display panel of claim 5, wherein the light reflecting layer further comprises a second light reflecting layer located between adjacent light emitting elements, and the second light reflecting layer is disposed on the insulation component and formed with the first light reflecting layer into one-piece structure.

7. The display panel of claim 1, wherein the light reflecting layer is made of a metal and the metal comprises at least one of aluminum or silver.

8. The display panel of claim 4, further comprising a light blocking layer, wherein the light blocking layer is located at a side of the second light reflecting layer away from the drive backplate.

9. The display panel of claim 8, wherein the light blocking layer is made of a black organic material.

10. The display panel of claim 1, wherein the light reflecting layer has a thickness of 500 Å-2000 Å.

11. A display apparatus, comprising a display panel comprising:
a drive backplate,
light emitting elements and a light reflecting layer, located on the drive backplate, wherein
the light reflecting layer comprises a first light reflecting layer wrapping sidewalls of the light emitting elements, and
the first light reflecting layer is configured to enable light emitted by each of the light emitting elements to be guided out from a top portion of the light emitting element.

12. A method of manufacturing a display panel, comprising:
placing a plurality of light emitting elements on a drive backplate;
forming a light reflecting film layer, wherein the light reflecting film layer at least covers sidewalls and a top surface of each of the plurality of light emitting elements;
coating a photoresist, wherein the photoresist exposes parts of the light reflecting film layer on the top surfaces of the plurality of light emitting elements; and,
etching the parts of the light reflecting film layer on the top surfaces of the plurality of light emitting elements to form a first light reflecting layer wrapping the sidewalls of the light emitting elements.

13. The method of claim 12, wherein the light reflecting film layer is made of a metal, and the metal comprises at least one of aluminum or silver.

14. The method of claim 13, comprising forming the light reflecting film layer by sputtering.

15. The method of claim 12, further comprising forming an insulation component at least between a bottom surface of the light emitting element and the drive backplate before forming the light reflecting film layer, wherein the insulation component isolates the light reflecting film layer and a bottom portion of the light emitting element in an insulating manner.

16. The method of claim 15, wherein the light reflecting film layer further covers the drive backplate, and
integrally forming a second light reflecting layer covering the drive backplate while forming the first light reflecting layer.

17. The method of claim 12, further comprising forming an insulation component covering the drive backplate before forming the light reflecting film layer, wherein the insulation component isolates the light reflecting film layer from a bottom portion of the light emitting element in an insulating manner.

18. The method of claim 15, wherein the light reflecting film layer further covers the insulation component, and
integrally forming a second light reflecting layer covering the insulation component while forming the first light reflecting layer.

19. The method of claim 12, further comprising removing the photoresist filled between any two adjacent light emitting elements and forming a light blocking layer between the any two adjacent light emitting elements.

20. The method of claim 19, wherein the light blocking layer is made of a black organic material.
